(19) United States
(12) Patent Application Publication
(10) Pub. No.: US 2025/0378854 A1
(43) Pub. Date: Dec. 11, 2025

(54) METHODS AND SYSTEMS FOR PVT AND AGING COMPENSATION OF FLASH CELLS

(71) Applicants: Vishal Sarin, SARATOGA, CA (US); Sankha SAHA, santa clara, CA (US); BIPRANGSHU SAHA, bangalore (IN); Sang T. Nguyen, union city, CA (US); Vikram Kowshik, Cupertino,, CA (US)

(72) Inventors: Vishal Sarin, SARATOGA, CA (US); Sankha SAHA, santa clara, CA (US); BIPRANGSHU SAHA, bangalore (IN); Sang T. Nguyen, union city, CA (US); Vikram Kowshik, Cupertino,, CA (US)

(21) Appl. No.: 19/057,814

(22) Filed: Feb. 19, 2025

Related U.S. Application Data
(63) Continuation-in-part of application No. 16/912,694, filed on Jun. 25, 2020, now Pat. No. 11,961,570.
Application No. 16/912,694 is a continuation-in-part of application No. 16/452,217, filed on Jun. 25, 2019, now Pat. No. 11,461,621.
(60) Provisional application No. 62/872,864, filed on Jul. 11, 2019.
(60) Provisional application No. 63/033,842, filed on Jun. 3, 2020.

(51) Int. Cl. G11C 5/00

(52) U.S. Cl. CPC G11C 5/005

(57) ABSTRACT

In one aspect, a system is configured for managing a change in cell characteristics due to process, voltage, temperature and aging of cells as well as any local variations of a flash cell array, comprising: a flash cell array subject to characteristic change and or local variation issue; a reference system comprising: a reference flash cell array comprising an “N” number of flash cells configured to overcome the characteristic change and or local variation issue by generating a reference voltage (CG_ref) that is applied to track the cell changes and local variations of the flash cell array; a reference current (I_ref) that is injected into the reference flash cell array to enable the reference array system to track the flash cell array; and a reference array bit-line driver system that maintains a same bit-line voltage (bl_ref) of both the flash cell array and the reference flash cell array; and a flash-cell current receiving unit coupled with the flash cell array and configured to receive the same bit-line voltage (bl_ref) of both the flash cell array and the reference flash cell array.

### CLAIM OF PRIORITY

This patent application claims priority to and is a continuation in part of U.S. patent application Ser. No. 18/240,349 filed on Aug. 30, 2023. This patent application is hereby incorporated by reference in its entirety.

U.S. patent application Ser. No. 18/240,349 claims priority to U.S. application Ser. No. 16/912,694 filed on Jun. 25, 2020. This patent application is hereby incorporated by reference in its entirety.

U.S. patent application Ser. No. 16/912,6940 claims priority to U.S. Provisional Application No. 63/033,842 filed on Jun. 3, 2020. This patent application is hereby incorporated by reference in its entirety.

U.S. patent application Ser. No. 16/912,6940 claims priority to U.S. Provisional Application No. 62/872,864 filed on Jul. 11, 2019. This patent application is hereby incorporated by reference in its entirety.

U.S. Provisional application Ser. No. 16/912,694 is a Continuation in-part of U.S. patent application Ser. No. 16/452,217 filed on Jun. 25, 2019. This patent application is hereby incorporated by reference in its entirety.

U.S. patent application Ser. No. 16/452,217 claims priority to U.S. Provisional Application No. 62/689,839 filed on Jun. 26, 2018. This patent application is hereby incorporated by reference in its entirety.

U.S. patent application Ser. No. 16/452,217 claims priority to U.S. Provisional Application No. 62/721,116 filed on Aug. 22, 2018. This patent application is hereby incorporated by reference in its entirety.

U.S. patent application Ser. No. 16/452,217 claims priority to U.S. Provisional Application No. 62/803,562 filed on Feb. 10, 2019. This patent application is hereby incorporated by reference in its entirety.

U.S. patent application Ser. No. 16/452,217 claims priority to U.S. Provisional Application No. 62/773,773 filed on Nov. 30, 2018. This patent application is hereby incorporated by reference in its entirety.

### BACKGROUND

### 1. Field

This application generally relates to electronic circuits, and more particularly to a system, method, and article of manufacture of PVT and aging compensation, such as threshold voltage drift in memory cells.

### 2. Background

The flash cell is widely used in non-volatile memories. Flash memory cells experience Process, Voltage, and Temperature (PVT) variations; and aging mechanisms such as threshold voltage drift which depends on temperature and time. The threshold voltage of flash cells naturally drifts over time as stored electrons leak from gate areas, also the effective threshold voltage changes with temperature. This drift causes the cell's current output to deviate from its originally programmed value. The cell characteristics change with the above factors and the variations in cell characteristics are similar when cells are in proximity or near each other (local variation). Because of its ability to store multiple threshold voltage (VT) levels, it attracts different analog operations to be implemented using flash cells. While it is useful in analog use, its variations with process, voltage and temperature (PVT) limits its application. The invention presented here deals with the problem and provides efficient compensation technique against PVT and ageing for memory cells in general and specifically for flash memory cells.

### SUMMARY OF THE INVENTION

In one aspect, a system is disclosed that is configured for managing a local variation (cell characteristic changes) of a flash cell array, comprising: a flash cell array subject to a local variation issue; a reference system comprising: a reference flash cell array comprising an “N” number of flash cells configured to overcome the local variation issue by generating a reference voltage (CG_ref) that is applied to track and offset changes in characteristics caused by process, voltage and temperature and threshold drift with time of the flash cell array; a reference current (I_ref) that is injected into the reference flash cell array to enable the reference array system to track the flash cell array; and a reference array bit-line driver system that maintains a same bit-line voltage (bl_ref) of both the flash cell array and the reference flash cell array; and a flash-cell current controlling unit coupled to the reference flash cell array and configured to receive the same bit-line voltage (bl_ref) of both the flash cell array and the reference flash cell array.

### BRIEF DESCRIPTION OF THE DRAWINGS

FIG. 1 illustrate an example flash cell array system which is PVT and ageing compensated, according to some embodiments.

FIG. 2 illustrates the flash cell with its important elements, according to some embodiments.

FIG. 3 illustrates an example circuit diagram of the invention disclosure, according to some embodiments.

FIG. 4 illustrates the bit-line voltage control and current receiving system for the PVT and ageing compensated flash cell array, according to some embodiments.

FIG. 5 illustrates an example process for implementation of PVT and aging compensation of flash cells, according to some embodiments.

The Figures described above are a representative set and are not exhaustive with respect to embodying the invention.

### DESCRIPTION

Disclosed are a system, method, and article of manufacture for PVT and aging compensation of flash cells. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment of the present invention. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of the embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

### Definitions

Example definitions for some embodiments are now provided.

A current mirror can be a circuit designed to copy a current through one active device by controlling the current in another active device of a circuit, keeping the output current constant regardless of loading.

GND refers to the universal Ground connection in electrical engineering. It is the reference point and represents a Zero potential for the entire circuit under discussion.

N-type metal-oxide-semiconductor logic uses n-type (−) MOSFETs (metal-oxide-semiconductor field-effect transistors) to implement logic gates and other digital circuits. nMOS transistors operate by creating an inversion layer in a p-type transistor body. This inversion layer, called the n-channel, can conduct electrons between n-type source and drain terminals. The n-channel is created by applying voltage to the third terminal, called the gate. nMOS transistors have four modes of operation: cut-off (or subthreshold), triode, saturation (sometimes called active), and velocity saturation. nMOS is complementary P-type metal-oxide-semiconductor logic uses p-type MOSFETS. pMOS transistors operate by creating an inversion layer in a n-type transistor body. This inversion layer, called the p-channel, can conduct electrons between p-type source and drain terminals.

Operational amplifier (herein ‘opamp’) can be a DC-coupled high-gain electronic voltage amplifier with a differential input an n-ended output (e.g. a single-ended output).

Process, Voltage, and Temperature (PVT) can refer to a set of parameters in semiconductor manufacturing that describes the variations in the manufacturing process, operating voltage, and/or temperature of a chip. This can impact its performance and are crucial factors considered during design and testing to ensure reliable operation across different environmental conditions. PVT can represent the range of potential variations a chip might experience due to manufacturing inconsistencies and operating voltage and temperature fluctuations.

A parasitic element is a circuit element that is possessed by an electrical component but which it is not desirable for it to have for its intended purpose.

### Example Computer Architecture and Systems

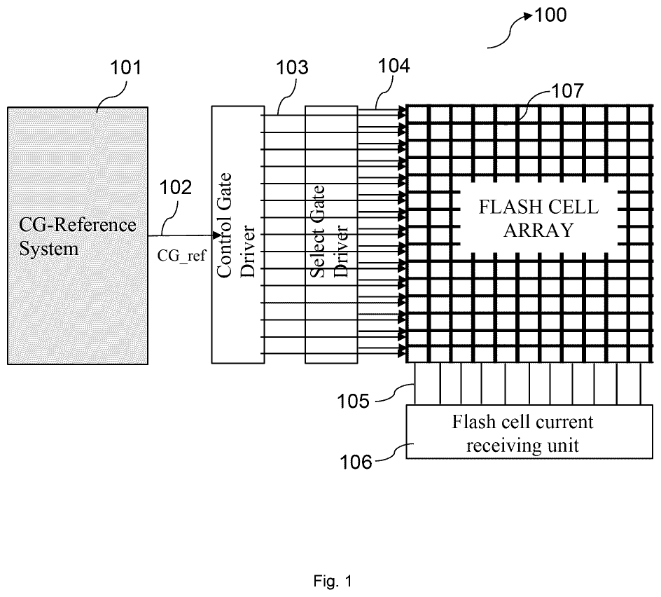

FIG. 1 illustrates an example flash memory array read system 100, according to some embodiments. Flash memory array read system 100 can include, inter alia: a Flash Cell array, control gate (CG), driver, select gate (SG) driver, flash-cell current receiving unit 106, and CG reference system 101. The CG reference system is designed to provide PVT and ageing compensation by changing CG_ref 102 voltage accordingly which is finally buffered and driven by the control gate driver system to the flash cell array 107 through the CG lines 103. Select Gate driver drives a logic high through the SG lines 104 to the flash cell array 107 when the array is intended to be accessed. Flash cell array 107 produces a current on the bit-line (bl) 105 which can be buffered by the flash cell current receiving unit 106 to make it useful for the rest of the circuit.

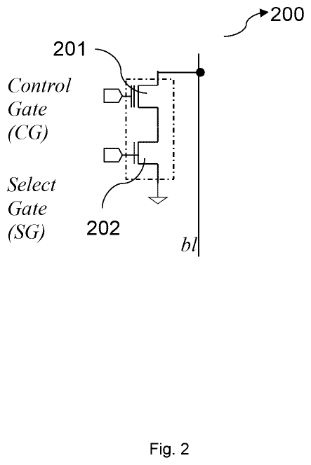

FIG. 2 demonstrates a flash cell 200 which consists of the flash element 201 and an NMOS 202 connected in series, according to some embodiments. The flash element gate terminal is the Control Gate (CG) and the NMOS gate terminal is used to enable the flash cell, hence named as select gate (SG). The flash cell is accessed logic-high at SG and respective analog voltage at CG. The respective analog CG voltage along with the programmed threshold voltage of the flash cell controls the current through the flash cell. The produced current on the flash cell is carried out to the respective receiving unit through the bit-line (bl). In an array of flash cells, a number of flash cells in a column are connected together on the bit-line (bl). Flash element displays a strong dependency on PVT and ageing, hence its current varieties significantly with PVT and ageing. The shift of the current with PVT and ageing results in a significant amount of error. The consequence of the shift is even fatal when the flash cell output current is being used in an analog system.

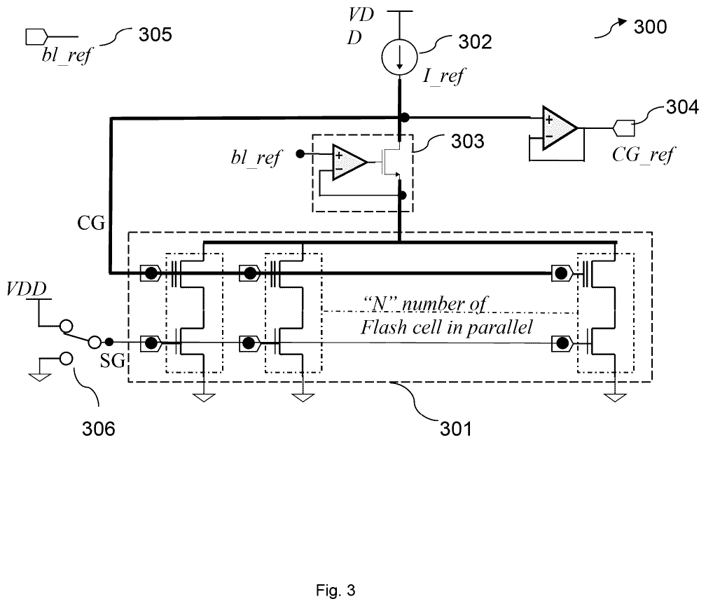

FIG. 3 represents an example system 300 of a circuit diagram of a CG-reference system, according to some embodiments. System 300 includes a CG-reference system that utilizes diode connected reference flash cell array to generate a reference voltage named as CG_ref to be applied to the flash cell array 107 (e.g. as presented in FIG. 1). A diode connected flash cell means that the control gate (CG) of the flash cell is connected to its drain node (D) either directly or through another transistor. System 300 comprises a reference flash cell array 301, a reference current I_ref 302, and a bit-line voltage control unit (reference array bit-line driver system) 303. The reference array 301 comprises of an “N” number of flash cells connected in parallel. A number of flash cells are used in 301 to overcome the local variation issue. A current I_ref 302 with the value of at least N*[lowest current of the operating range of the flash cell array 107] is injected into the diode-connected reference array 301. To make the reference array system 301 track the flash cell array 107 it is required to maintain a same bit-line voltage bl_ref 305 of both systems. To maintain the bl_ref at the reference array bit-line the bit-line driver system 303 is used inside the diode-connected system. The reference array SG (select gate) is connected to logic high through switch 306, the switch can be used to connect the SG to logic low when the reference array is not in use and need to be in a low leakage state. Due to changes in PVT and ageing the programmed VT on the flash cell array 107 in FIG. 1 shifts. Effectively, this same shift does occur at the reference array 301 as well. The diode-connected system generates the CG which is buffered to generate CG_ref, tracks the PVT and ageing and does necessary compensation on the flash cell 107. Due to the PVT or ageing if the VT shifts up the current from the flash cell in array 107 reduces. The same shift occurs at the reference array as well. The diode-connected reference array when faces higher VT, it's CG level also goes up hence the CG_ref 304. The CG_ref finally is applied to the CG terminal of the flash cell in flash cell array 107. Finally, the flash cell with higher VT and higher control gate voltage produces the same amount of current as before. This can result in a compensating PVT and an ageing effect.

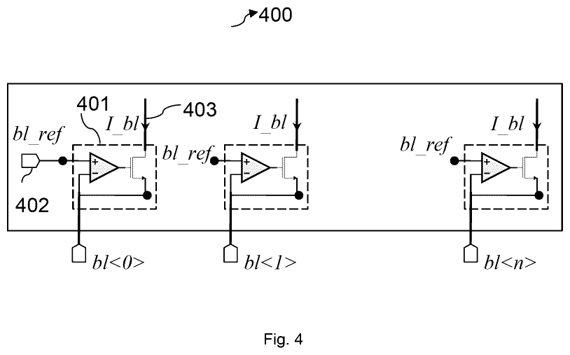

FIG. 4 shows the bit-line voltage control unit (also the current receiving unit) of the flash cell array 107 of FIG. 1, according to some embodiments. The bit-line voltage control unit (current receiving unit) utilizes the same bit-line driver system 401 and bl_ref 402 as used in FIG. 3 invention disclosure. The opamp maintains a constant voltage at bit-line (bl) which is equal to bl_ref. The flash cell with control gate (CG) at CG-reference-system 101 generated CG_ref of FIG. 3 and bit-line (bl) at bl_ref driven by current receiving system 400 generates a current which buffered and replicated at node 403 to be used by the rest of the circuit.

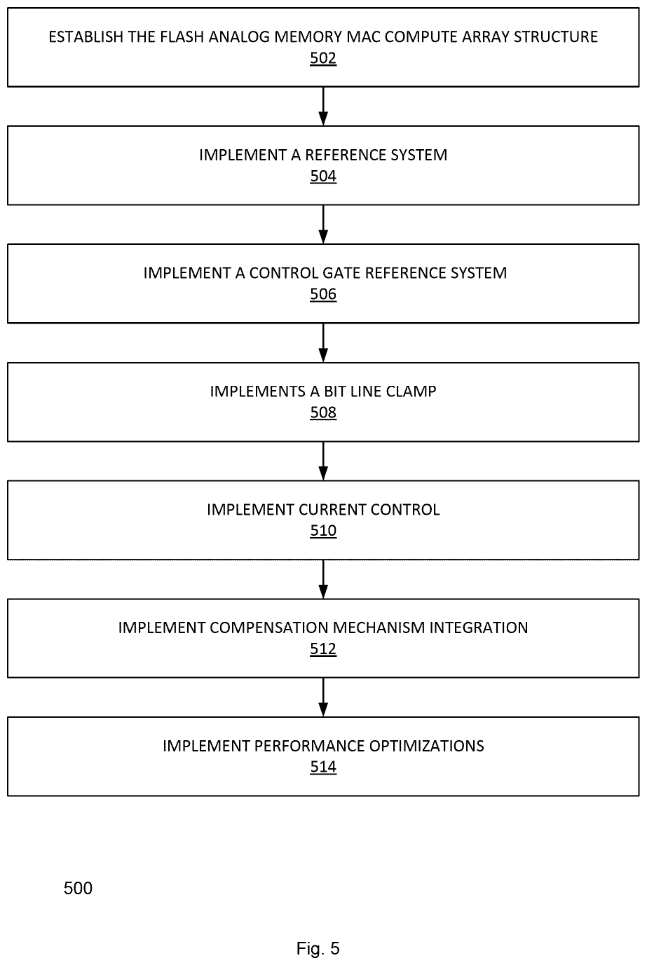

FIG. 5 illustrates an example process 500 for implementation of PVT and aging compensation of flash cells, according to some embodiments. In some examples, process 500 can be used in a Flash Memory System with Temperature and Drift Compensation (and/or other types of Error Compensation, etc.).

In step 502, process 500 establishes the flash analog memory MAC compute array structure. This can include arranging flash memory cells in a matrix configuration with x-number of cells per row and y-number of rows. Each cell can be configured to connect with both select gate and control gate drivers.

In step 504, process 500 implements a Reference System. The reference system can be implemented first, as it forms the foundation for drift and temperature compensation. This involves creating a reference cell array using identical flash cells as the main array. These reference cells can be programmed with the main array to ensure matching drift characteristics.

In step 506, process 500 implements a Control Gate Reference System. The control gate reference system can include an implementation of an operational amplifier configuration that maintains constant current through reference cells. The Control Gate Reference System is designed to adjust control gate voltage automatically in response to threshold variations, whether caused by temperature changes or time-based drift.

In step 508, process 500 implements a Bit Line Clamp. A bit line clamp system can be established to maintain consistent voltage conditions. This can involve implementing operational amplifiers configured to maintain a fixed reference voltage (e.g. millivolts) on the bit lines. The same bit line reference voltage should be applied to both reference cells and main array cells.

In step 510, process 500 implements Current Control. The system can be configured to establish specific current levels corresponding to stored values. For example, process 500 can program cells to generate precisely controlled currents for example ranging from one to one hundred and twenty-seven nanoamps, with each current level representing a different stored value. The control gate voltage can be calibrated to maintain these current levels despite threshold variations.

In step 512, process 500 implements Compensation Mechanism Integration. The compensation mechanism can implement integration of feedback loops that monitor reference cell behavior and adjust control gate voltage accordingly. When threshold drift occurs, the system can automatically modify control gate voltage to maintain constant current levels. This same principle can also apply to temperature-induced variations.

It is noted that verification and testing can be implemented as well. In some examples, process 500 can include comprehensive testing of the compensation mechanisms. This can include verifying that current levels remain stable across temperature variations and over extended time periods. The system should demonstrate consistent performance even as threshold voltages drift from their initial programmed values.

In step 514, process 500 implements Performance Optimizations. Various adjustments can be made to optimize system performance. For example, process 500 can fine-tune the bit line reference voltage for optimal operation. Process 500 can calibrate reference current levels for accurate compensation. Process 500 can adjust feedback loop parameters for responsive yet stable operation. Process 500 can verify compensation effectiveness across the full operating temperature range.

In this way, process 500 can ensure a robust system capable of maintaining stable current levels despite the inherent variations in memory cells in general and specifically flash memory cell characteristics over time and temperature.

### CONCLUSION

A system to track changes in PVT and drift in non-volatile memory cells is disclosed so as to maintain constant currents in memory arrays by using reference cells to generate reference bias voltages in a manner that the reference bias voltages supplied to the memory arrays change to offset any variations in cell current from PVT and threshold drift. It is understood that the same mechanism can be used to track changes with PVT and drift in resistance or other parameters depending on the kind of memory used.

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

Accordingly, the specification and drawings are to be regarded in an illustrative rather than a restrictive sense. In some embodiments, the machine-readable medium can be a non-transistor form of machine-readable medium.

What is claimed as new and desired to be protected by Letters Patent of the United States is:

1. A system configured for managing changes in characteristics of a flash cell array, comprising:
a flash cell array subject to a cell characteristic change and or local variation issue;
a reference system comprising:
a reference flash cell array comprising an “N” number of flash cells configured to overcome the characteristic changes and or local variation issue by generating a reference voltage (CG_ref) that is applied to track and compensate for changes in flash cell characteristics and or local variation of the flash cell array;
a reference current (I_ref) that is injected into the reference flash cell array to enable the reference array system to track and compensate for characteristic changes and/or local variation of the flash cell array; and
a reference array bit-line driver system that maintains a same bit-line voltage (bl_ref) for both the flash cell array and the reference flash cell array; and
a flash-cell current receiving, and bit-line voltage maintaining unit coupled with the flash cell array and configured to receive the same bit-line voltage (bl_ref) of both the flash cell array and the reference flash cell array.

2. The system of claim 1, wherein the reference system comprises a control gate (CG) reference system.

3. The system of claim 1, wherein memory array select gate (SG) of the reference system is connected to a logic high state when memory cells are enabled to be read; and is connected to a logic low state when the memory cells are disabled to be in an off state.

4. The system of claim 1, wherein when due to changes in the cell characteristics and or local variations, as the programmed threshold voltage on each flash cell of the flash cell array shifts, the reference flash cell array also undergoes the same shift and is configured to generate a buffered CG_ref voltage which tracks the change and generates a CG_ref voltage to compensate for the changes and keep cell currents of the flash memory array constant.

5. The system of claim 1, wherein the characteristic change and or location variation issue comprises a process, voltage and temperature (PVT) issue or an aging issue.

6. The system of claim 5, wherein due to the PVT issue or the aging issue the threshold voltage shifts up or down and the current from the flash cell array reduces or increases respectively.

7. The system of claim 6, wherein when the diode-connected reference array faces a higher threshold voltage, the CG_ref level also increases, and when the diode-connected reference array faces a lower threshold voltage, the CG_ref level also decreases.

8. The system of claim 7, wherein the CG_ref is applied to a CG terminal of each flash cell in the flash cell array.

9. The system of claim 8, wherein a flash cell with a higher threshold voltage and higher control gate voltage produces the same amount of current as before to result in compensation for cell characteristics change due to PVT or ageing issue; and or compensates for local variations.

10. The system of claim 8, wherein a flash cell with a lowered threshold voltage and lowered control gate voltage produces the same amount of current as before to result in compensation for cell characteristics change due to PVT or ageing issue; and or compensates for local variations.

11. The system of claim 1, wherein the reference flash cell array comprises “N” number of flash cells connected in parallel.

12. The system of claim 1, wherein the I_ref comprises a value higher than N*[lowest current of an operating range of the flash cell array].

13. The system of claim 1, wherein circuit to maintain the bl_ref voltage at the reference array bit-line, and bit line current drive system is used inside the diode-connected reference array system.

14. The system of claim 1, wherein the cell characteristic change and or local variation comprises one or more variations with process, voltage, and temperature (PVT) of flash cells.

15. The system of claim 1, wherein the characteristic change and or local variation issue comprises one or more mechanisms of threshold voltage drift and aging compensation of flash cells.
